(19) United States
(12) Patent Application Publication
(10) Pub. No.: US 2003/0170970 A1
(43) Pub. Date: Sep. 11, 2003

(54) Semiconductor device and method of manufacturing the same

(76) Inventors: Kouji Senoo, Yamanashi (JP); Hiroyuki Nagai, Yamanashi (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/344,748

(22) PCT Filed: Aug. 14, 2001
(86) PCT No.: PCT/JP01/07017

(30) Foreign Application Priority Data
Aug. 15, 2000 (JP) 2000-246494

(51) Int. Cl. H01L 21/4763

(52) U.S. Cl. 438/596

(57) ABSTRACT

A semiconductor device having reduced interconnect delay and increased interconnect reliability and a method of manufacturing the same are provided. A plurality of interconnects 12a through 12f are formed on a base insulating layer 10 with different interconnect pitches P1 through P3. Next, an adhesion inhibiting layer inhibiting adhesion to an interlayer insulating layer 16 formed on the interconnects is formed in the space between adjacent interconnects of a smaller interconnect pitch in which space the interconnect delay is predicted to exceed a predetermined value due to interconnect design. In a formed semiconductor device 18, gaps of a small dielectric constant are formed in the spaces between interconnects of the smaller interconnect pitches (parts C), while an insulating film is buried selectively in the spaces between interconnects of the larger interconnect pitches (parts A and B).

### BACKGROUND OF THE INVENTION

1. Field of the Invention

The present invention relates to semiconductor devices and methods of producing the same.

2. Description of the Related Art

Normally, a semiconductor device is formed by providing a plurality of interconnects and a plurality of electronic components on a substrate using a wafer.

In this case, when the interconnects are formed to project on the substrate by dry etching, for instance, the surface of the substrate on which surface the interconnects are not formed is further covered, and at the same time, the spaces between the interconnects are filled with an interlayer insulating layer. Further, in this case, when the interlayer insulating layer is formed in multiple layers, the process of forming the interconnects and the process of forming the interlayer insulating layer are repeated a desired number of times. Alternately, the interconnects are also buried and formed in the substrate by a damascene process.

In the above-described semiconductor device, interconnect delay becomes an issue. The interconnect delay is proportional to the electric resistance of metal employed in the interconnects and the parasitic capacitance between the interconnect and the substrate or between the interconnects. With the recent progress of miniaturization, an increase in the electric resistance due to a decreased interconnect width and an increase in the parasitic capacitance due to a reduced interconnect pitch have become noticeable, thereby increasing the interconnect delay.

In order to reduce the interconnect delay, a material having a small dielectric constant is selected as the interlayer insulating layer, or it is considered to increase the interconnect pitch, at the stage of circuit designing, at a point where the interconnect delay becomes a problem.

On the other hand, there has been proposed a so-called air isolation method that reduces the dielectric constant between interconnects approximately to the level of air by omitting the interlayer insulating layer between interconnects, that is, by forming a gap between interconnects.

Of the above-described conventional methods, however, the former method of selecting a material of a small dielectric constant as the interlayer insulating layer can do no more than reduce the dielectric constant to at most two, and therefore, does not necessarily achieve the effect of reducing the interconnect delay sufficiently. Further, the progressing miniaturization leaves only a little room for the method of increasing the interconnect pitch to be employed. Particularly, the interconnect pitch may be unchangeable due to layout restrictions on the disposition of electronic components. Thus, this method does not necessarily achieve the effect of reducing the interconnect delay sufficiently, either.

On the other hand, the latter air isolation method, which still has a lot of problems including the securing of interconnect reliability, that is, the prevention of the deformation or breaking of the formed interconnects, has yet to be put to practical use.

### SUMMARY OF THE INVENTION

The present invention is made in view of the above-described problems, and has an object of providing a semiconductor device having reduced interconnect delay and increased reliability and a method of manufacturing the same.

In order to achieve this object, a semiconductor device according to the present invention, which is formed by forming an insulating layer on a base insulating layer on which at least two or more interconnects are formed so as to project therefrom, is characterized in that the insulating layer is buried selectively in a space between adjacent interconnects in which space interconnect delay is predicted to fall below a predetermined value due to interconnect design.

Here, interconnect delay is proportional to each of the electric resistance of an interconnect and the parasitic capacitance between interconnects. The former electric resistance and the latter capacitance are inversely proportional to the interconnect width and the interconnect pitch, respectively. Therefore, the magnitude of the interconnect delay can be predicted with respect to each interconnect. Accordingly, in the interconnect design, the space between interconnects where the interconnect delay exceeds a predetermined value and the space between interconnects where the interconnect delay falls below the predetermined value can be specified.

As previously described, the air isolation method, which forms a gap between interconnects, can reduce the interconnect delay. On the other hand, no insulating film is buried in the spaces between interconnects, so that the formed interconnects may be deformed or broken. Meanwhile, according to the present invention, an insulating film is buried selectively in the space between adjacent interconnects where the interconnect delay is predicted to fall below a predetermined value due to the interconnect design. Therefore, the interconnect delay is reduced, so that a semiconductor device having high interconnect reliability can be obtained.

In this case, according to the semiconductor device, of the base insulating layer and the insulating layer provided on and under the adjacent interconnects, one is formed of hydrophilic material and the other is formed of hydrophobic material. Thereby, a semiconductor device in which a gap is suitably formed can be obtained. At this point, for instance, both upper and lower insulating layers (interlayer insulating layers) may be formed of hydrophilic material, and a special layer formed of hydrophobic material may be provided between the upper and lower interlayer insulating layers.

Further, in this case, the semiconductor device is suitably formed by alternately forming the interconnects and the insulating layer so that two or more layers of the interconnects and two or more layers of the insulating layer are formed. The interconnects of the second layer are formed on the first insulating layer (interlayer insulating layer) so as to project therefrom, and the second insulating layer (interlayer insulating layer) is formed on the first insulating layer and the interconnects of the second layer.

Further, a method of manufacturing a semiconductor device according to the present invention, which method includes an interconnect forming step of forming at least two or more interconnects on a substrate so that the interconnects project therefrom and an interlayer insulating layer forming step of forming an interlayer insulating layer, is characterized by including an adhesion inhibiting layer forming step of forming an adhesion inhibiting layer inhibiting adhesion to the interlayer insulating layer between the interconnect forming step and the interlayer insulating layer forming step.

In the interconnect forming step, at least two or more interconnects may be suitably formed on the substrate so that the interconnects project therefrom by, for instance, a method forming an interconnect layer and thereafter performing dry etching using a predetermined mask. However, this is not the only method.

Further, in the interlayer insulating layer forming step, the interlayer insulating layer may be suitably formed by a method applying inorganic or organic insulating material paste. However, this is not the only method.

Further, in the adhesion inhibiting layer forming step, the adhesion inhibiting layer inhibiting adhesion may be suitably formed by a method forming one of the interlayer insulating layer and the adhesion inhibiting layer of hydrophilic material and the other of hydrophobic material in light of reducing wettability. For instance, a method that applies by printing or attaches by surface processing an adhesion inhibiting material only to the region between adjacent interconnects in which region the interconnect delay is predicted to exceed a predetermined value due to the interconnect design is employable. However, this is not the only method.

By the above-described configuration of the present invention, by balancing the adhesiveness of the surface and the surface tension, viscosity, and self-weight of the insulating paste, a space between adjacent interconnects of a smaller interconnect pitch is prevented from being filled with an insulating film, while a space between adjacent interconnects of a larger interconnect pitch is filled with an insulating film. Therefore, the adhesion inhibiting layer can be suitably formed with a reduced number of steps, so that a semiconductor device having a small interconnect delay can be obtained.

Further, in this case, the adhesion inhibiting layer is more preferably formed in the space between adjacent interconnects in which space the interconnect delay is predicted to exceed the predetermined value. Thereby, it is ensured that the insulating film is buried in the space between adjacent interconnects of the larger interconnect pitch, so that a semiconductor device in which interconnect deformation and breaking is reduced can be obtained.

Further, in this case, the interconnect forming step and the interlayer insulating layer forming step may be repeated two or more times, and an insulating paste viscosity control step of controlling viscosity of insulating paste that is a material forming the interlayer insulating layer so as to prevent the insulating paste from entering only the space between adjacent interconnects may be performed at least once as a replacement for the adhesion inhibiting layer forming step.

Further, the effects of the present invention may also be produced, without providing the adhesion inhibiting layer forming step, by the interlayer insulating layer forming step including the insulating paste viscosity control step of controlling viscosity of insulating paste that is a material forming the interlayer insulating layer so as to prevent the insulating paste from entering only the space between adjacent interconnects.

In this case, normally, the adjacent interconnects where the interconnect delay is predicted to exceed the predetermined value have a small interconnect pitch when the interconnects are formed to have a uniform width. Accordingly, by controlling the viscosity of the insulating paste to a value large enough to prevent the insulating paste from entering and filling the space of the small interconnect pitch, a gap can be left in the space between the adjacent interconnects. The predetermined viscosity of the insulating paste can be suitably set by collecting data by repeating the test of applying and forming insulating pastes of different viscosities on a substrate with different interconnect pitches.

### BRIEF DESCRIPTION OF THE DRAWINGS

FIG. 1 is a block diagram of a manufacturing process for illustrating a method of manufacturing a semiconductor device according to a first embodiment;

FIG. 2 is a fragmentary sectional view of a semiconductor device for illustrating the method of manufacturing a semiconductor device according to the first embodiment, showing a process of forming a base insulating layer;

FIG. 3 is a fragmentary sectional view of the semiconductor device for illustrating the method of manufacturing a semiconductor device according to the first embodiment, showing a process of forming interconnects;

FIG. 4 is a fragmentary sectional view of the semiconductor device for illustrating the method of manufacturing a semiconductor device according to the first embodiment, showing a process of forming an adhesion inhibiting layer;

FIG. 5 is a fragmentary sectional view of the semiconductor device for illustrating the method of manufacturing a semiconductor device according to the first embodiment, showing a process of forming an interlayer insulating layer;

FIG. 6 is a fragmentary sectional view of the semiconductor device for illustrating the method of manufacturing a semiconductor device according to the first embodiment, showing a process of forming additional interconnects;

FIG. 7 is a fragmentary sectional view of the semiconductor device for illustrating the method of manufacturing a semiconductor device according to the first embodiment, showing a process of forming an additional adhesion inhibiting layer;

FIG. 8 is a fragmentary sectional view of the semiconductor device for illustrating the method of manufacturing a semiconductor device according to the first embodiment, showing a process of forming an additional interlayer insulating layer;

FIG. 9 is a fragmentary sectional view of a semiconductor device according to a second embodiment of the present invention;

FIG. 10 is a fragmentary sectional view of a semiconductor device according to a third embodiment of the present invention; and

FIG. 11 is a fragmentary sectional view of a semiconductor device according to a fourth embodiment of the present invention.

### DETAILED DESCRIPTION OF THE PREFERRED EMBODIMENTS

A description will now be given, with reference to the drawings, of preferred embodiments of a semiconductor device and a method of manufacturing the same according to the present invention.

[First Embodiment]

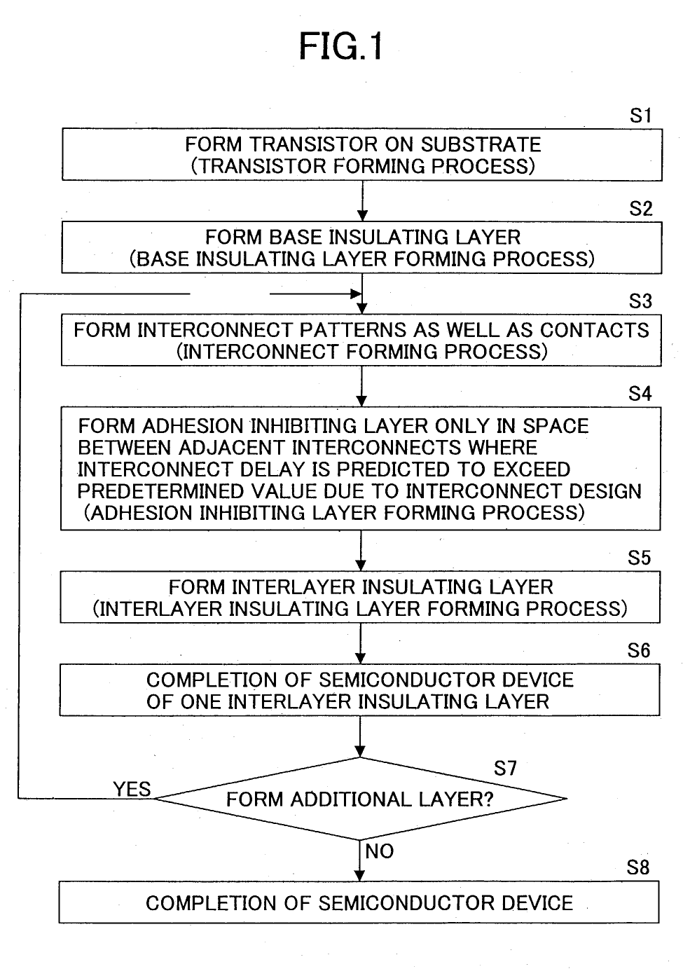

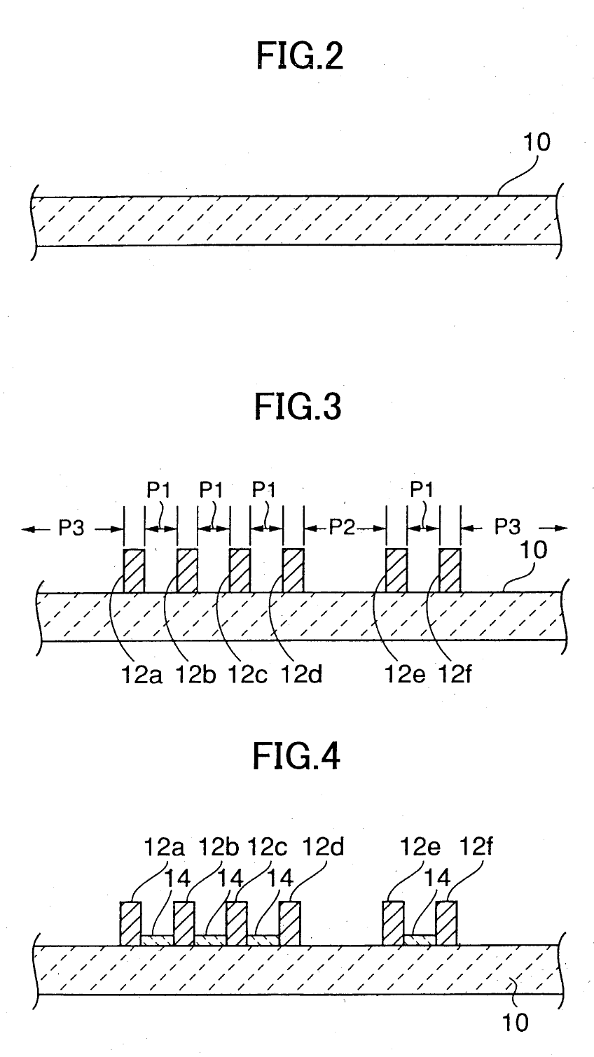

A description will be given of a semiconductor device and a method of manufacturing the same according to the first embodiment with reference to the flowchart of FIG. 1 and the fragmentary sectional views of the semiconductor device of FIGS. 2 through 8.

First, for instance, a transistor (semiconductor device) is formed on a substrate formed of a wafer (a transistor forming process S1, the substrate and the transistor not shown in the drawings). Next, a base insulating layer 10 including SiO₂-based TEOS (tetraethylorthosilicate), for instance, is formed on it (a base insulating layer forming process S2, FIG. 2).

Next, an interconnect layer is formed on the base insulating layer 10. A plurality of interconnects (interconnect patterns) 12a through 12f are formed by dry etching with different interconnect pitches P1 through P3 (an interconnect forming process S3, FIG. 3). In this case, Al is employed as the interconnect material. At this point, together with the formation of the interconnects, necessary contact holes are formed in the base insulating layer 10, and contacts are further formed (not shown in the drawing).

Next, an adhesion inhibiting layer for inhibiting adhesion to a later-described interlayer insulating layer is formed only in the space between adjacent interconnects where the interconnect delay is predicted to exceed a predetermined value due to the interconnect design (an adhesion inhibiting layer forming process S4, FIG. 4).

Specifically, in this case, the interconnect delay is predicted to exceed the predetermined value in the spaces between the interconnects 12a and 12b, 12b and 12c, 12c and 12d, and 12e and 12f having the smaller interconnect pitches (P1 in FIG. 3). On the other hand, the interconnect delay is predicted to fall below the predetermined value in the spaces between the interconnects 12d and 12e, the interconnect 12a and its adjacent interconnect not shown in the drawing, and the interconnect 12f and its adjacent interconnect not shown in the drawing having the larger interconnect pitches (P2 and P3 in FIG. 3). Accordingly, for instance, with a mask, not shown in the drawing, being provided in the spaces between the interconnects 12d and 12e, the interconnect 12a and its adjacent interconnect not shown in the drawing, and the interconnect 12f and its adjacent interconnect not shown in the drawing having the larger interconnect pitches, the spaces between the interconnects 12a and 12b, 12b and 12c, 12c and 12d, and 12e and 12f having the smaller interconnect pitches are coated with an adhesion inhibiting agent, so that an adhesion inhibiting layer 14 is formed. In this case, instead of the method of providing the coating of the adhesion inhibiting agent, HMDS (hexamethyldisilazane) vapor, for instance, may be caused to circulate in the chamber as the adhesion inhibiting agent so that surface processing is performed.

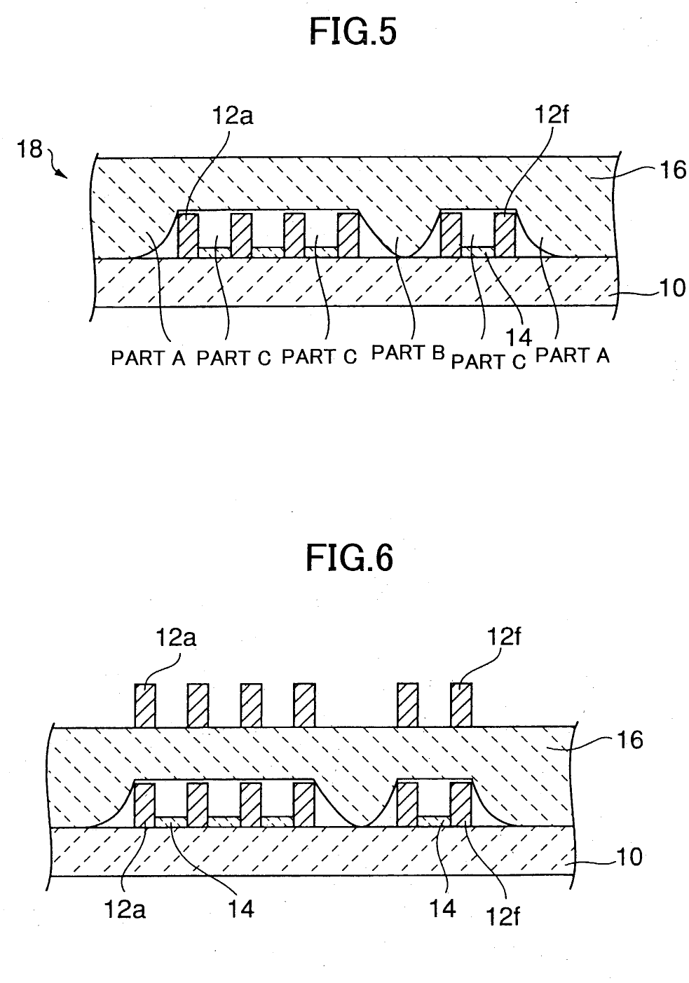

Next, MSQ (methyl silsesquioxane), which is a hydrophilic inorganic material, for instance, is applied so that an interlayer insulating layer 16 is formed (an interlayer insulating layer forming process S5, FIG. 5). At this point, the interlayer insulating layer 16 adheres to the part of the base insulating layer 10 in which part the adhesion inhibiting layer 14 is not formed so that the insulating film is filled in the spaces between the adjacent interconnects (parts A and B in FIG. 5). The interlayer insulating layer 16, however, does not adhere to the part of the base insulating layer 10 in which part the adhesion inhibiting layer 14 is formed so that gaps are formed between the adjacent interconnects (parts C in FIG. 5). FIG. 5 provides a pictorial or schematic representation for convenience of description.

After the above-described interlayer insulating layer forming process (S5) is completed, baking and curing are further performed (not shown in the drawings). Thereby, a semiconductor device 18 having an interlayer insulating layer formed on a substrate on which interconnects are formed to project therefrom, or having an interconnect layer and an interlayer insulating layer formed therein, is completed (S6, FIG. 5).

In this case, successively thereafter, the above-described interconnect forming process, adhesion inhibiting layer forming process, and interlayer insulating layer forming process may be further repeated one or a plurality of times as required so that a semiconductor device having multiple interconnect layers and interlayer insulating layers formed therein is formed.

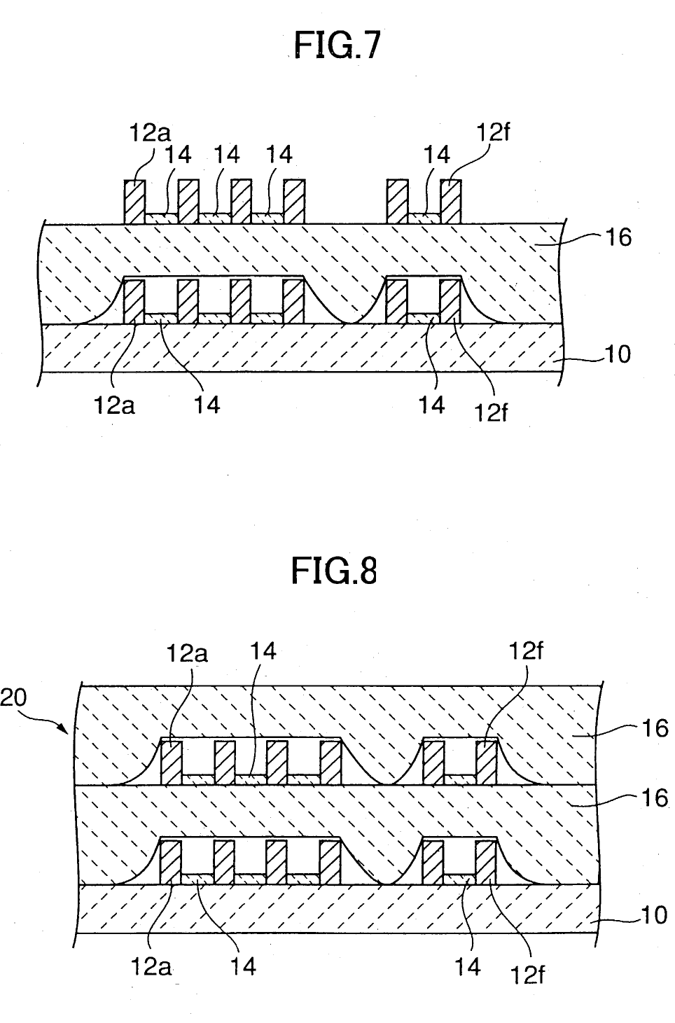

That is, successively after step 6 (S6), the interconnect forming process (FIG. 6), the adhesion inhibiting layer forming process (FIG. 7), and the interlayer insulating layer forming process (FIG. 8) that are steps 3 (S3) through 5 (S5), and processes including baking are performed (a multilayer forming process S7, FIGS. 6 through 8). Thereby, a semiconductor device 20 having multiple interconnect layers and interlayer insulating layers formed therein is completed (step 8, FIG. 8).

In the semiconductor devices 18 and 20 having the above-described configurations according to the first embodiment, a gap is formed between the adjacent interconnects having a small interconnect pitch. Therefore, the dielectric constant between the interconnects decreases so as to reduce the interconnect delay. Further, since an insulating film is buried selectively in a space between adjacent interconnects of a large interconnect pitch, the interconnect reliability can be secured.

In forming the plural interlayer insulating layers of the above-described semiconductor device 20, the adhesion inhibiting layer is provided for intervention for each of the interlayer insulating layers for the purpose of inhibiting adhesion. Instead of this, as a method of inhibiting the adhesion of any one of the interlayer insulating layers, a later-described method of controlling the viscosity of insulating paste in forming the interlayer insulating layers may be employed.

[Second Embodiment]

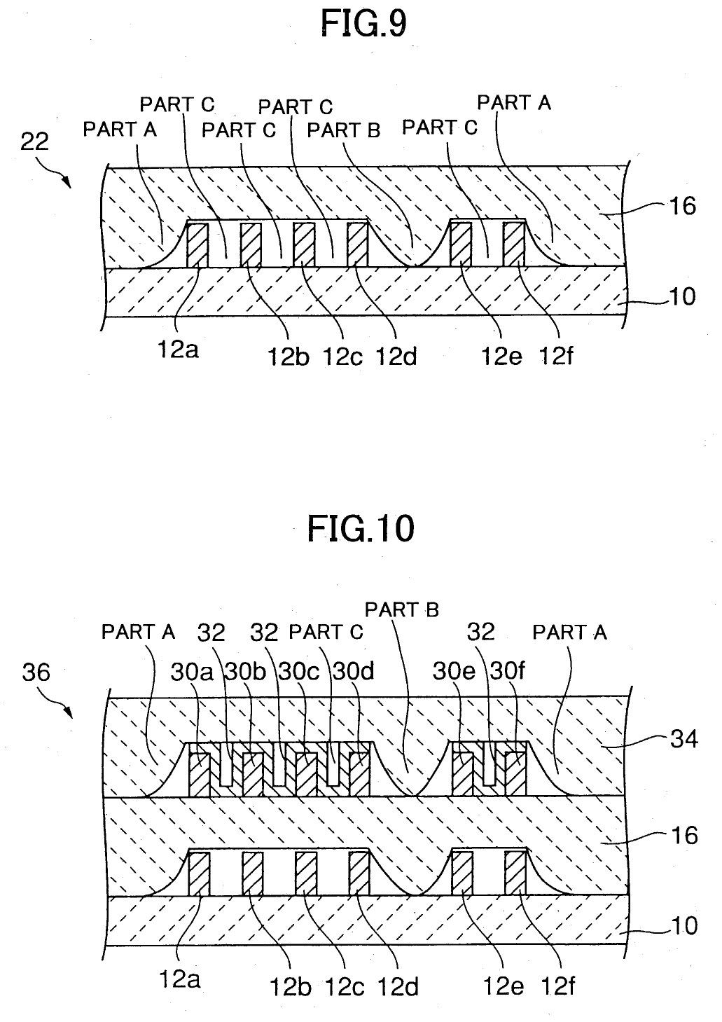

Next, a description will be given, with reference to FIG. 9, of a semiconductor device and a method of manufacturing the same according to the second embodiment. In the second embodiment and the subsequent embodiments, the method of manufacturing a semiconductor device is basically the same. Therefore, the same elements as those of the first embodiment are referred to by the same numerals as those of the first embodiment, and a graphical representation of each manufacturing process will be omitted. Further, a description of the processes of manufacturing second and subsequent interlayer insulating layers will be omitted.

First, after forming a transistor on a substrate (a transistor forming process), the base insulating layer 10 including TEOS is formed on it (a base insulating layer forming process). Further, the interconnects 12a through 12f are formed using Al material on the base insulating layer 10 by dry etching with the different interconnect pitches P1 through P3 (see FIG. 3) (an interconnect forming process), and contacts are formed.

Next, SiLK (a registered trademark of The Dow Chemical Company), which is a hydrophobic organic material, for instance, is applied as insulating paste so that the interlayer insulating layer 16 is formed (an interlayer insulating layer forming process). At this point, after controlling the viscosity of SiLK to a predetermined value so as to prevent SLK from entering the spaces between the adjacent interconnects 12a and 12b, 12b and 12c, 12c and 12d, and 12e and 12f having the smaller interconnect pitches (P1) in which spaces the interconnect delay is predicted to exceed a predetermined value due to the interconnect design (an insulating paste viscosity controlling process), SLK is applied on the base insulating layer 10. The viscosity is controlled by changing the proportion of a solvent for SiLK.

Thereby, the interlayer insulating layer 16 is caused to adhere to the base insulating layer 10 in the parts (parts A and B in FIG. 9) having no interconnect formed therein between the interconnects 12d and 12e, the interconnect 12a and its adjacent interconnect not shown in the drawing, and the interconnect 12f and its adjacent interconnect not shown in the drawing provided with the larger interconnect pitches (P2 and P3). Meanwhile, the interlayer insulating layer 16 is prevented from adhering to the base insulating layer 10 in the parts (parts C in FIG. 9) between the interconnects 12a and 12b, 12b and 12c, 12c and 12d, and 12e and 12f where the viscosity is high so as to make it difficult for SLK to enter. Accordingly, gaps are formed in the parts C.

Thereby, a semiconductor device 22 having an interconnect layer and an interlayer insulating layer formed therein is completed (FIG. 9).

In the semiconductor devices 22 according to the above-described second embodiment, a gap is formed between the adjacent interconnects having a small interconnect pitch. Therefore, the dielectric constant between the interconnects decreases so as to reduce the interconnect delay. Further, since an insulating film is buried selectively in a space between adjacent interconnects of a large interconnect pitch, the interconnect reliability can be secured.

[Third Embodiment]

Next, a description will be given, with reference to FIG. 10, of a semiconductor device and a method of manufacturing the same according to the third embodiment.

First, each layer is formed as in the semiconductor device 22 of the above-described second embodiment. That is, after forming the interconnects 12a through 12f using Al on the base insulating layer 10 (an interconnect forming process), SiLK whose viscosity is controlled to a predetermined value is applied so that the interlayer insulating layer 16 is formed (an interlayer insulating layer forming process). Then, curing and other processes for stabilizing the interlayer insulating layer 16 are performed.

Next, the second interconnect and interlayer insulating layers are formed by a method somewhat different from that in the case of the first layers.

That is, before forming the second interlayer insulating layer after interconnects 30a through 30f of the second layer are provided to project from the first interlayer insulating layer 16, an oxide film 32 of hydrophilic SiO₂ is formed by, for instance, CVD selectively in the spaces between the interconnects 30a and 30b, 30b and 30c, 30c and 30d, and 30e and 30f having the smaller interconnect pitches (P1).

Next, like the first interlayer insulating layer 16, a second interlayer insulating layer 34 is formed by applying SiLK whose viscosity is controlled to the predetermined value (an interlayer insulating layer forming process). At this point, the hydrophilic oxide film 32 is formed in the spaces between the interconnects 30a and 30b, 30b and 30c, 30c and 30d, and 30e and 30f having the smaller interconnect pitches (P1). Therefore, in the parts C, the hydrophobic interlayer insulating layer 34 is prevented from adhering to the hydrophobic interlayer insulating layer 16 (parts C in FIG. 10), so that gaps are formed. On the other hand, the hydrophobic interlayer insulating layer 34 suitably adheres to the exposed hydrophobic interlayer insulating layer 16 in the spaces between the interconnects 30d and 30e, 30a and its adjacent interconnect not shown in the drawing, and 30f and its adjacent interconnect not shown in the drawing having the larger interconnect pitches (P2 and P3) (parts A and B in FIG. 10).

Thereby, a semiconductor device 36 having multiple interconnect layers and interlayer insulating layers formed therein is completed (FIG. 10).

In the semiconductor device 36 according to the above-described third embodiment, a gap is formed between the adjacent interconnects having a small interconnect pitch. Therefore, the dielectric constant between the interconnects decreases so as to reduce the interconnect delay. Further, since an insulating film is buried selectively in a space between adjacent interconnects of a large interconnect pitch, the interconnect reliability can be secured.

[Fourth Embodiment]

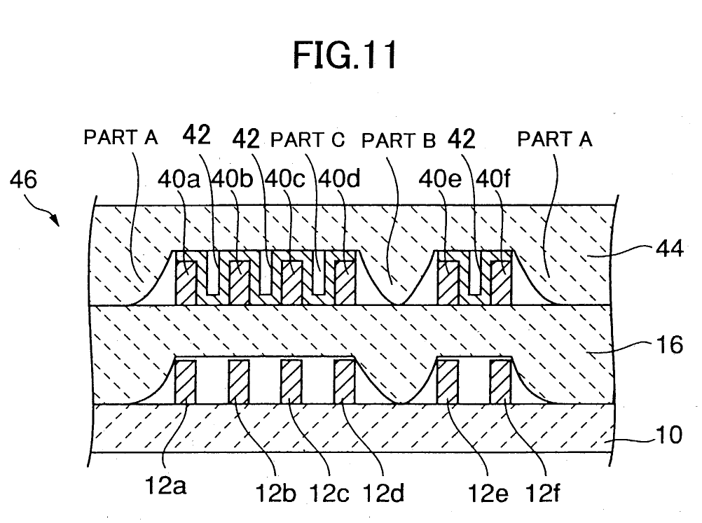

Next, a description will be given, with reference to FIG. 11, of a semiconductor device and a method of manufacturing the same according to the fourth embodiment.

First, each layer is formed as in the semiconductor device 22 of the above-described second embodiment. That is, after the interconnects 12a through 12f are formed using Al on the base insulating layer 10 (an interconnect forming process), SiLK whose viscosity is controlled to a predetermined value is applied so that the interlayer insulating layer 16 is formed (an interlayer insulating layer forming process). Then, curing and other processes for stabilizing the interlayer insulating layer 16 are performed.

Next, the second interconnect and interlayer insulating layers are formed by a method different from that in the case of the first layers.

That is, before forming the second interlayer insulating layer after interconnects 40a through 40f of the second layer are formed to project from the first interlayer insulating layer 16, an organic thin film 42 of polymer material is formed by, for instance, CVD selectively in the spaces between the interconnects 40a and 40b, 40b and 40c, 40c and 40d, and 40e and 40f having the smaller interconnect pitches (P1, see FIG. 3). The degree of the hydrophobic property of the first hydrophobic interlayer insulating layer 16 can be further increased by forming the organic thin film 42 thereon. As is apparent from the following description, the organic thin film 42 serves as a layer inhibiting adhesion (an adhesion inhibiting layer forming process).

Next, as in the case of the above-described first embodiment, MSQ, which is inorganic material, is applied, so that a second interlayer insulating layer 44 is formed (an interlayer insulating layer forming process).

At this point, compared with in the spaces between the interconnects 40d and 40e, 40a and its adjacent interconnect not shown in the drawing, and 40f and its adjacent interconnect not shown in the drawing, hydrophobicity is increased in the spaces between the interconnects 40a and 40b, 40b and 40c, 40c and 40d, and 40e and 40f in which spaces the organic thin film 42 is formed. Therefore, the interlayer insulating layer 44 adheres to the interlayer insulating layer 16 in the former (parts A and B in FIG. 11), while in the latter, the interlayer insulating layer 44 is prevented from adhering to the interlayer insulating layer 16 (organic thin film 42) (parts C in FIG. 9) so that gaps are formed in the parts C. In this case, by controlling the viscosity of MSQ to a predetermined value, the effect of the viscosity control and the effect of the organic thin film 42 are combined with each other to be suitably produced.

Thereby, a semiconductor device 46 having a plurality of interconnect layers and interlayer insulating layers are formed therein is completed (FIG. 11). In this semiconductor device 46, the hydrophobic interlayer insulating film 16 and the hydrophilic interlayer insulating film 44 are alternately layered.

In the semiconductor device 46 according to the above-described fourth embodiment, a gap is formed between the adjacent interconnects having a small interconnect pitch. Therefore, the dielectric constant between the interconnects decreases so as to reduce the interconnect delay. Further, since an insulating film is buried selectively in a space between adjacent interconnects of a large interconnect pitch, the interconnect reliability can be secured.

The method of manufacturing a semiconductor device of the present invention is not limited to the above-described first through fourth embodiments. In the adhesion inhibiting layer forming process, the adhesion inhibiting layer may be formed over the entire surface of the substrate.

Thereby, by balancing the adhesiveness of the surface and the surface tension, viscosity, and self-weight of the insulating paste, a space between adjacent interconnects of a smaller interconnect pitch is prevented from being filled with an insulating film, while a space between adjacent interconnects of a larger interconnect pitch is filled with an insulating film, so that the effects of the present invention can be produced with a reduced number of processes.

What is claimed is:

1. (Amended) A semiconductor device formed by forming an insulating layer on a base insulating layer on which at least two or more interconnects are formed to project therefrom, characterized in that:
the insulating layer is buried selectively in a space between adjacent interconnects in which space interconnect delay is predicted to fall below a predetermined value due to interconnect design.

2. (Amended) The semiconductor device as claimed in claim 1, characterized in that of the base insulating layer and the insulating layer provided on and under the adjacent interconnects, one is formed of hydrophilic material and the other is formed of hydrophobic material.

3. The semiconductor device as claimed in claim 1 or 2, characterized in that the interconnects and the insulating layer are alternately formed so that two or more layers of the interconnects and two or more layers of the insulating layer are formed.

4. A method of manufacturing a semiconductor device, the method including an interconnect forming step of forming at least two or more interconnects on a substrate so that the interconnects project therefrom and an interlayer insulating layer forming step of forming an interlayer insulating layer, characterized by including:
an adhesion inhibiting layer forming step of forming an adhesion inhibiting layer inhibiting adhesion to the interlayer insulating layer between the interconnect forming step and the interlayer insulating layer forming step.

5. The method of manufacturing a semiconductor device as claimed in claim 4, characterized in that the adhesion inhibiting layer is formed only in a space between adjacent interconnects in which space interconnect delay is predicted to exceed a predetermined value due to interconnect design.

6. The method of manufacturing a semiconductor device as claimed in claim 4, characterized in that of the interlayer insulating layer and the adhesion inhibiting layer, one is formed of hydrophilic material and the other is formed of hydrophobic material.

7. (Amended) The method of manufacturing a semiconductor device as claimed in claim 4 or 5, characterized in that the interconnect forming step and the interlayer insulating layer forming step are repeated two or more times, and an insulating paste viscosity control step of controlling viscosity of insulating paste that is a material forming the interlayer insulating layer so as to prevent the insulating paste from entering only the space between adjacent interconnects is performed at least once as a replacement for the adhesion inhibiting layer forming step.

8. A method of manufacturing a semiconductor device, the method including an interconnect forming step of forming at least two or more interconnects on a substrate so that the interconnects project therefrom and an interlayer insulating layer forming step of forming an interlayer insulating layer, characterized in that:
the interlayer insulating layer forming step comprises an insulating paste viscosity control step of controlling viscosity of insulating paste that is a material forming the interlayer insulating layer so as to prevent the insulating paste from entering only a space between adjacent interconnects in which space interconnect delay is predicted to exceed a predetermined value due to interconnect design.

9. The method of manufacturing a semiconductor device as claimed in any of claims 4, 5, and 8, characterized in that the interconnect forming step and the interlayer insulating layer forming step are repeated two or more times.
